(19) United States
(12) Patent Application Publication
(10) Pub. No.: US 2007/0122649 A1
(43) Pub. Date: May 31, 2007

(54) Thin film transistor substrate for display

(76) Inventors: Je-Hun Lee, Seoul (KR); Shi-Yul Kim, Yongin-si (KR); Do-Hyun Kim, Seoul (KR); Byeong-Beom Kim, Daejeon (KR); Chang-Oh Jeong, Suwon-si (KR); Jun-Young Lee, Yongin-si (KR); Yang-Ho Bae, Suwon-si (KR); Sung-Wook Kang, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/595,395

(22) Filed: Nov. 8, 2006

(30) Foreign Application Priority Data
Nov. 8, 2005 (KR) 2005-106274

(51) Int. Cl. B32B 15/20; B32B 19/00; C23C 14/00; B05D 1/36

(52) U.S. Cl. 428/674; 428/698; 427/402; 204/192.15

(57) ABSTRACT

A conductive structure containing copper is capable of being etched to have a reliable profile where the copper layer is free of corrosion or oxidation includes a barrier layer formed on an insulating or semiconductor substrate followed by a copper layer, a blocking layer and a capping layer. The copper layer includes copper or copper alloy. The barrier layer includes molybdenum (Mo), molybdenum nitride (MoN) or molybdenum alloy which includes at least one of MoW, MoTi, MoNb or MoZr. The blocking layer includes copper nitride, copper oxide or copper oxinitride. The capping layer includes molybdenum, molybdenum nitride (MoN) or molybdenum alloy which includes at least one of MoW, MoTi, MoNb and MoZr.

### CROSS-REFERENCE TO RELATED APPLICATIONS

This application relies for priority upon Korean Patent Application No. 2005-106274 filed on Nov. 8, 2005, the contents of which are herein incorporated by reference in its entirety.

### FIELD OF THE INVENTION

The present invention relates to a conductive structure for use in a thin film transistor such as may be useful in the manufacture of liquid crystal and organic light-emitting displays and, more particularly, to a conductive structure that includes copper or copper alloy.

### DESCRIPTION OF THE RELATED ART

A thin film transistor (TFT) substrate may be used in a liquid crystal display (LCD) or in an organic light-emitting device (OLED) display. An LCD includes two substrates having electrodes, and liquid crystal layer disposed therebetween. When electric fields are generated between the two electrodes, the arrangement of the liquid crystal molecules is changed, altering its optical transmissivity. An OLED displays an image by using organic electroluminescent material. Each pixel of the OLED includes a driving TFT that provides the organic electroluminescent material with current and a switching TFT controlling the driving TFT.

As the size of an LCD apparatus or OLED increases, the gate lines and data lines become longer and their electrical resistance increases thereby delaying the transference of signals. Conductive structures made of lower resistance materials such as copper (Cu) would appear to be desirable. Copper has a resistivity of about 1.67 μΩcm (about 2.0 μΩcm to about 2.3 μΩcm in a thin film state). In contrast, aluminum (Al) has a resistivity of about 2.65 μΩcm (about 3.1 μΩcm in a thin film state). In short, copper (Cu) has a much lower resistivity than that of aluminum (Al). Therefore, when copper is employed as the gate line and the data line, the signal-delaying problem may be solved.

However, copper has poor adhesion to insulting substrates such as to a glass substrate or a semiconductor layer. Furthermore, copper ions rapidly defuse into an amorphous silicon (a-Si) or silicon (Si) layer when a TFT is operated and copper ions generated by the etchant (or etching solution) used in etching the conductive structure, or during stripping of the photo resist pattern may penetrate an amorphous silicon layer to create leakage currents affecting the performance of the TFT. Additionally, silicon ions can also diffuse into a copper conductive structure raising its resistivity and lowering its chemical resistance to corrosion.

As a result, copper alone is not used and, instead, a multi-layered structure that includes a barrier layer, a copper layer formed on barrier layer and a capping layer formed on copper layer is used. However, copper layer may be corroded by a galvanic effect arising during etching/patterning of the multi-layered structure or during the stripping of the photo resist pattern to causing an undesired overhang of the capping layer and defective side profile.

### SUMMARY OF THE INVENTION

The present invention provides a multi-layered conductive structure having a side profile that can reliably be patterned and in which a corrosion and oxidation free copper layer is tightly attached to the substrate. An exemplary conductive structure comprises a barrier layer, a copper layer, a blocking layer and a capping layer. An additional blocking layer may be included between barrier layer and the copper layer. Barrier layer and the capping layer may each include molybdenum (Mo), molybdenum nitride (MoN) or a molybdenum alloy such as one or more of MoW, MoTi, MoNb or MoZr. The blocking layer may comprise copper nitride, copper oxide or copper oxinitride.

In an exemplary method of manufacturing the conductive structure, a barrier layer is formed on a substrate. A copper layer including copper or copper alloy is formed on barrier layer. A blocking layer is formed on copper layer. Then, a capping layer is formed on the blocking layer. The blocking layer may be formed by a sputtering method using copper as a target in a chamber filled with nitrogen or nitrogen gas or a combination of oxygen and nitrogen gas or by a vacuum break.

An exemplary TFT substrate includes a gate conductive structure, a data conductive structure and a pixel electrode. The gate conductive structure includes a gate line that is formed on an insulation substrate and extends along a first direction and a gate electrode that is electrically connected to the gate line. The data conductive structure includes a data line that is formed on the insulation substrate so that the data line is electrically insulated from the gate line, a source electrode electrically connected to the data line, and a drain electrode that is spaced apart from the source electrode. The data line extends along a second direction that is different from, and advantageously orthogonal to, the first direction. The pixel electrode is electrically connected to the drain electrode. The pixel electrode is formed in a pixel area defined by the gate line and the data line. Either or both of the gate conductive structure and the data conductive structure includes a barrier layer, a copper layer, a blocking layer and a capping layer.

### BRIEF DESCRIPTION OF THE DRAWING

The above and other features and advantages of the present invention will become more apparent from a reading of the ensuing description, together with the drawing, in which:

FIG. 1 is a schematic cross-sectional view illustrating a structure of a TFT conductive structure according to an example embodiment of the present invention;

FIG. 2 is a schematic cross-sectional view illustrating a profile defect of a conventional multi-layer conductive structure;

FIGS. 3A to 3D are cross-sectional views illustrating a method of manufacturing a TFT conductive structure according to an example embodiment of the present invention;

FIG. 4 is a cross-sectional view illustrating a TFT conductive structure according to another example embodiment of the present invention;

FIG. 5A is a layout illustrating a TFT substrate according to an example embodiment of the present invention;

FIGS. 5B and 5C are cross-sectional views taken along a line B-B′ in FIG. 5A;

FIGS. 6A, 7A, 8A and 9A are plan views illustrating a method of manufacturing a TFT substrate according to an example embodiment of the present embodiment;

FIGS. 6B and 6C are cross-sectional views taken along a line B-B′ in FIG. 6A;

FIGS. 7B and 7C are cross-sectional views taken along a line B-B′ in FIG. 7A;

FIGS. 8B and 8C are cross-sectional views taken along a line B-B′ in FIG. 8A;

FIGS. 9B and 9C are cross-sectional views taken along a line B-B′ in FIG. 9A;

FIG. 10A is a layout illustrating a TFT substrate according to another example embodiment of the present invention;

FIGS. 10B and 10C are cross-sectional views taken along a line B-B′ in FIG. 10A; and

FIG. 11 is a graph showing a density of nitrogen or oxygen in the conductive structure.

### DESCRIPTION OF EXAMPLARY EMBODIMENTS

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the singular forms “a,” “an” and “the” are intended to include the plural forms as well, unless the context clearly indicates otherwise. The regions illustrated in the figures are to be understood as being schematic in nature and variations from the shapes of the illustrations as a result, for example, of manufacturing techniques and/or tolerances, are to be expected. Thus, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

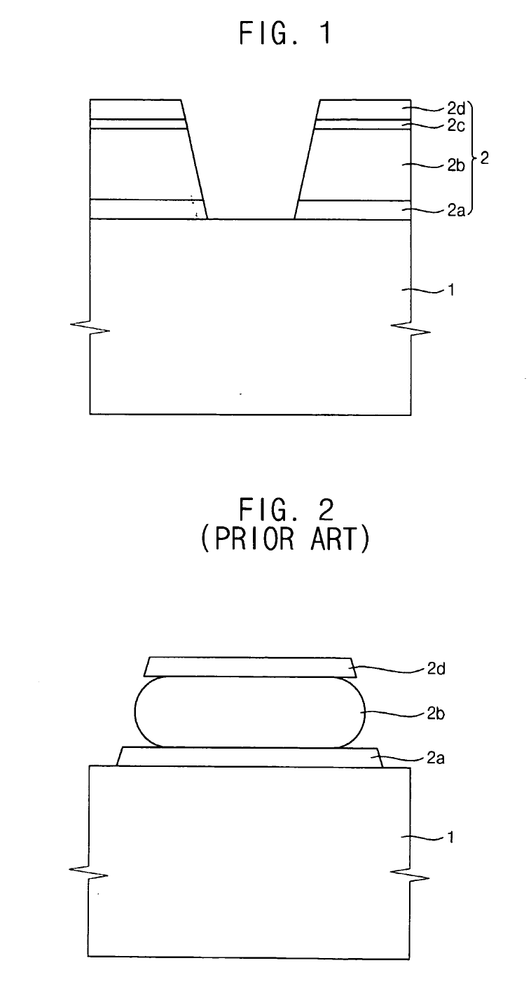

FIG. 1 is a schematic cross-sectional view illustrating a structure of a TFT conductive structure 2 according to an example embodiment of the present invention. Barrier layer 2a is formed on a substrate 1 and a copper layer 2b made of copper or a copper alloy is formed on the barrier layer. A capping layer 2d is formed on copper layer 2b, and a blocking layer 2c is disposed between copper layer 2b and capping layer 2d. Substrate 1 may comprise either a single layer or a complex structure including a plurality of elements, devices, layers, such as an insulating glass or silicon substrate or a semiconductor layer including amorphous silicon, an insulation layer, etc. Barrier layer 2a strengthens the adhesion between substrate 1 and copper layer 2b and prevents copper ions from diffusing into substrate 1 and preferably exhibits similar etching selectivity to that of copper layer 2b so that they may be simultaneously etched. Exemplary materials for barrier layer 2a include molybdenum (Mo), molybdenum nitride (MoN) and molybdenum alloy such as MoTi, MoNb, MoZr, etc.

In order to prevent corrosion of copper layer 2b by etching solutions used in patterning, capping layer 2d covers and protects the copper layer. Capping layer 2d is comprised of a material having a relatively high chemical resistance to prevent copper layer 2b from being corroded by the etching solution for patterning. Preferably, capping layer 2d is comprised of a material having similar etching selectivity to that of copper layer 2b so that capping layer 2d and copper layer 2b are simultaneously etched. Capping layer 2d includes, for example, molybdenum (Mo), molybdenum nitride (MoN) and molybdenum alloy such as MoW, MoTi, MoNb, MoZr, etc.

FIG. 2 is a schematic cross-sectional view illustrating a profile defect of a conventional multi-layer conductive structure. Referring to FIG. 2, when barrier layer 2a is formed below copper layer 2b, and capping layer 2d is formed on copper layer 2b, galvanic corrosion occurs at the boundary of barrier layer 2a and copper layer 2b and at the boundary of capping layer 2d and copper layer 2b. The galvanic corrosion arises from an electron exchange during a process of etching a conductive structure and a process of removing photo resist pattern. Therefore, the copper layer 2b is improperly etched creating a defective profile in which an overhang of capping layer 2d may cause the structure to crack during processing.

According to the present invention, in order to prevent galvanic corrosion, blocking layer 2c is disposed between copper layer 2b and capping layer 2d as shown in FIG. 1. Blocking layer 2c may include for example, a dielectric material. Alternatively, blocking layer 2c may include a semiconductor material. Even when blocking layer 2c includes a semiconductor material, blocking layer 2c prevents electron exchanged to reduces overhang of capping layer 2d induced by galvanic corrosion.

Alternatively, blocking layer 2c may include a metal compound, such as a copper compound to simplify the manufacturing process. For example, blocking layer 2c may include copper nitride, copper oxide, copper oxinitride (sometimes referred to as copper oxynitride), etc. Examples of copper nitride include Cu₃N, etc. Examples of copper oxide include Cu₂O, CuO, etc. Examples of copper oxinitride include a mixture of copper oxide and copper nitride such as Cu₃N+CuO, Cu₃N+Cu₂O, etc. Atomic percent of nitrogen or oxygen in copper nitride or copper oxide of the blocking layer is in a range of about 0.001 to 50 atomic % (hereinafter, referred to as at %).

The thickness of blocking layer 2c is determined by the degree of insulation desired. When the atomic percent of nitrogen or oxygen increases, the degree of insulation increases so that blocking layer 2c may be made thinner. On the contrary, when atomic percent of the nitrogen or oxygen decreases, the degree of insulation decreases requiring a thicker blocking layer. Furthermore, when blocking layer 2c exhibits some small conductivity, a thicker blocking layer is required. For example, blocking layer 2c may range in thickness from about 50 angstroms to about 1000 angstroms.

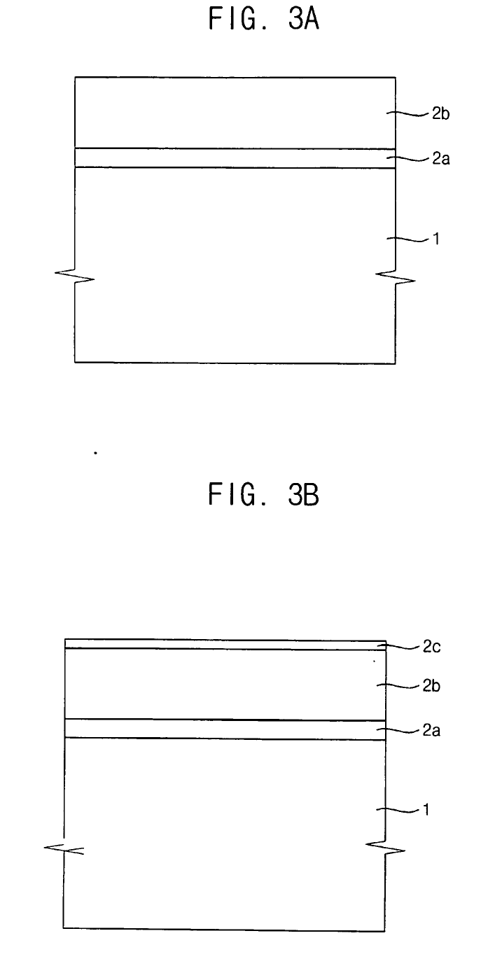

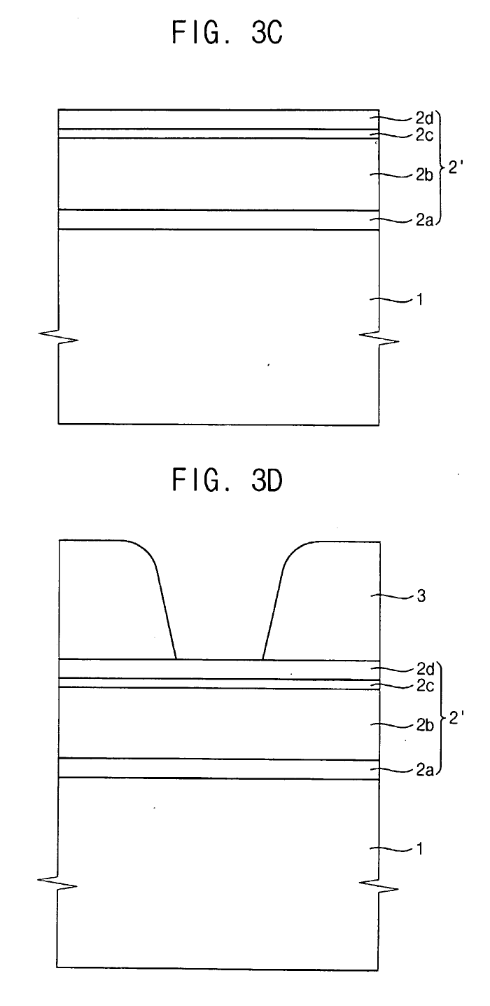

Referring to FIG. 3A, substrate 1 may be made of an insulating material such as a glass or a semiconductor. Barrier layer 2a having a thickness of about 100 angstroms to about 300 angstroms is formed by, for example, by sputtering a material including molybdenum (Mo), molybdenum nitride (MoN), Molybdenum alloy such as MoW, MoTi, MoNb, MoZr, etc. Then, copper layer 2b is formed on barrier layer 2a by, for example sputtering copper or copper alloy. For example, copper layer 2b having a thickness of about 1500 angstroms to about 2500 angstroms may be formed by collision of argon ions and copper or copper alloy. The amount of argon gas is then reduced and nitrogen gas is allowed to flow into the sputtering chamber. Unlike the inert argon gas, when the nitrogen gas is ionized and collides with copper or copper alloy, the ionized nitrogen chemically reacts with copper or copper alloy to form copper nitride.

A copper nitride layer formed on copper layer 2b corresponds to blocking layer 2c. However, all of copper atoms are not chemically reacted with nitride. Therefore, copper atoms collided with argon gas, or copper atoms that are not chemically reacted with nitride gas may be included in blocking layer 2c together with copper nitride.

The ratio of argon gas to nitrogen gas in the chamber is, for example, in a range of about 90 to 10 through about 40 to 60. When the ratio of argon gas to nitrogen gas in the chamber is, for example, in a range of about 90 to 10 through about 40 to 60, blocking layer 2c may include nitrogen of about 0.001 at % to about 50 at %, and blocking layer 2c has a thickness of about 50 angstroms to about 1000 angstroms.

Blocking layer 2c including copper oxide such as Cu₂O, CuO, etc., may be formed by providing the chamber with oxygen gas (O₂) together with argon gas (Ar). Blocking layer 2c including copper oxinitride, such as Cu(O,N)x, etc., may be formed through providing the chamber with, for example, a mixed gas of oxygen gas (O₂) and nitrogen gas (N₂), a mixed gas of oxygen gas (O₂) and ammonia gas (NH₃), nitrous oxide gas (N₂O), nitrogen oxide gas (NO), nitrogen dioxide gas (NO₂), etc. together with argon gas (Ar). By adjusting mixture ratio, a ratio of nitrogen atoms or oxygen atoms to copper atoms may be adjusted.

Furthermore, the process of forming blocking layer 2c may be performed in a chamber containing nitrogen gas or oxygen gas. In detail, the process of forming blocking layer 2c may be formed in a chamber that is different from the chamber in which a previous process is performed.

When a multi-layer is formed through sputtering, the ratio of nitrogen and oxygen between layers may be adjusted through an operation of a vacuum break. In detail, after barrier layer 2a is formed on the substrate 1 and copper layer 2b is formed on barrier layer 2a, the vacuum is ended or air is injected into the chamber. Then, a copper oxide layer is formed on copper layer 2b due to oxygen of air. Copper oxide layer may be employed as a portion of blocking layer 2c.

As shown in FIG. 3C, capping layer 2d is formed on blocking layer 2c through a sputtering method using argon gas. A material, which may be simultaneously wet etched together with copper layer 2b or which may have a similar etching selectivity to that of copper layer 2b, may be employed as the sputtering target, which corresponds to material included in capping layer 2d. Molybdenum group, for example, molybdenum (Mo), Molybdenum nitride (MoN), or molybdenum alloy such as MoW, MoTi, MoNb, MoZr, etc. may be employed as the above material. In this way, multi-layer 2′ having four layers of barrier layer 2a, copper layer 2b, blocking layer 2c and capping layer 2d are formed.

A, a photo resist layer is formed on the multi-layer 2′, and the photo resist layer is exposed and developed to form a photo resist pattern 3 defining conductive structures. By using the photo resist pattern 3 as an etching mask, capping layer 2d, blocking layer 2c, copper layer 2b and barrier layer 2a are simultaneously etched to expose the substrate 1. Hydrogen peroxide or etching solution based on nitric acid may be used as an etching solution. The above etching solution may further include phosphoric acid, acetic acid, etc. When barrier layer 2a is exposed by wet etching capping layer 2d, blocking layer 2c and copper layer 2b, barrier layer 2a may be patterned to form conductive structure 2 by using the photo resist pattern 3 to expose the substrate 1.

Barrier layer 2a may be patterned by dry etching using gas such as HCl, Cl₂, H₂, O₂, or a mixture thereof. When barrier layer 2a is not etched by the etching solution, the substrate 1 is prevented from being deteriorated due to the etching solution including copper ions, since barrier layer 2a covers the substrate 1. Then, the photo resist pattern 3 is removed. As a result, the conductive structure 2 in FIG. 1 is completed. Hereinbefore, barrier layer 2a is, for example, dry-etched by using the photo resist pattern 3 as an etching mask. Alternatively, when capping layer 2d, blocking layer 2c and copper layer 2b are etched to define an over-layer, the photo resist pattern may be removed and barrier layer 2a may be dry-etched to form the conductive structure 2 by using the over-layer as an etching mask.

Conductive structure 2 formed through the above-mentioned process will not be damaged by galvanic corrosion because the blocking layer disposed between the copper layer and capping layer blocks electrons. Overhang is prevented and the profile of conductive structure 2 has a satisfactory tapered angle.

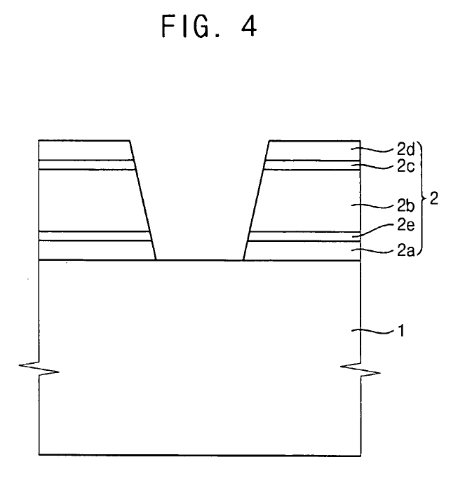

Another example of a conductive structure and a method of manufacturing the conductive structure will be explained. FIG. 4 is a cross-sectional view illustrating a TFT conductive structure according to another example embodiment of the present invention. The conductive structure is substantially the same as that in FIG. 1 except for an additional blocking layer 2e disposed between barrier layer 2a and copper layer 2b. Hereinafter, blocking layer 2c is referred to as a ‘first blocking layer’, and the additional blocking layer 2e is referred to as a ‘second blocking layer’.

Referring to FIG. 4, second blocking layer 2e disposed between barrier layer 2a and copper layer 2b to prevent electron-exchange between barrier layer 2a and copper layer 2b. Second blocking layer 2e may include dielectric material. Alternatively, second blocking layer 2e may include semiconductor material. Even when second blocking layer 2e includes the semiconductor layer, second blocking layer 2e prevents the majority of the electron exchange to reduce corrosion of copper layer 2b, which corresponds to galvanic corrosion. Likewise second blocking layer 2e, the first blocking layer 2c may include dielectric material or semiconductor material. Preferably, the first and second blocking layers 2c and 2e may include metal alloy that may be simultaneously etched with copper layer 2b in order to simplify a manufacturing process. Second blocking layer 2e may include copper nitride, copper oxide, copper oxinitride, etc. Examples of copper nitride include Cu₃N, etc. Examples of copper oxide include Cu₂O, CuO, etc. Examples of copper oxinitride include a mixture of copper oxide and copper nitride such as Cu₃N+CuO, Cu₃N+CU₂O, etc.

The atomic percent of nitrogen or oxygen in copper nitride, copper oxide copper oxinitride of the blocking layer is in the range of about 0.001 to 50 atomic % (hereinafter, referred to as at %) in order to prevent galvanic corrosion. When second blocking layer 2e is formed together with the first blocking layer 2c, more satisfactory conductive structure profile may be obtained.

Hereinafter, a process of manufacturing second blocking layer 2e will be explained in detail. Substrate 1 such as an insulating glass substrate, a semiconductor layer, an insulating layer, etc. is prepared. Then, barrier layer 2a is formed by, for example, sputtering a material including molybdenum (Mo), molybdenum nitride (MoN), molybdenum alloy such as MoTi, MoNb, MoZr, etc. Barrier layer 2a is formed such that barrier layer 2a has a thickness of about 100 angstroms to about 300 angstroms.

An inert gas such as argon gas and a reactive gas such as nitrogen gas are admitted to a sputtering chamber (not shown) using a target of copper or copper alloy. Then, second blocking layer 2e is formed. Unlike argon gas which is inert gas, when nitrogen gas is ionized to form nitrogen ions, and the nitrogen ions collide with the target of copper or copper alloy, the nitrogen ions react against the target of copper or copper alloy. Therefore, when the target includes copper or copper alloy, the nitrogen ions react with the copper or copper alloy to form copper nitride. As a result, second blocking layer 2e including copper nitride is formed on barrier layer 2a.

However, not all of the copper atoms chemically react to form copper nitride. Therefore, copper atoms collided with argon gas, or copper atoms that are not chemically reacted with nitride gas may be included in the second blocking layer 2e, together with copper nitride. The ratio of argon gas to nitrogen gas in the chamber is, for example, in a range of about 90 to 10 through about 40 to 60. When the ratio of argon gas to nitrogen gas in the chamber is, for example, in a range of about 90 to 10 through about 40 to 60, second blocking layer 2e may include nitrogen of about 0.001 at % to about 50 at %, and second blocking layer 2e has a thickness of about 50 angstroms to about 1000 angstroms.

Blocking layer 2c including copper oxide such as Cu₂O, CuO, etc. may be formed through providing the chamber with oxygen gas (O₂) together with argon gas (Ar). Blocking layer 2c including copper oxinitride such as Cu(O,N)x, etc. may be formed through providing the chamber with, for example, a mixed gas of oxygen gas (O₂) and nitrogen gas (N₂), a mixed gas of oxygen gas (O₂) and ammonia gas (NH₃), nitrous oxide gas (N₂O), nitrogen oxide gas (NO), nitrogen dioxide gas (NO₂), etc. together with argon gas (Ar). By adjusting mixture ratio, a ratio of nitrogen atoms or oxygen atoms to copper atoms may be adjusted. Then, providing the chamber with nitrogen gas or oxygen gas is stopped, and copper layer 2b is formed on second blocking layer 2e by sputtering with a copper target or a copper alloy target under a condition of argon gas.

Then, nitrogen gas or oxygen gas is provided and reactive sputtering is performed to form the first blocking layer 2c including copper nitride, copper oxide or copper oxinitride. The first blocking layer 2c may be formed through a vacuum break as described referring to FIG. 3B. Second blocking layer 2e and barrier layer 2a may be formed in a same chamber through an in-situ process, but the first blocking layer 2c may be formed through reactive sputtering in a different chamber filled with nitrogen gas and oxygen gas. As described in the above embodiment, capping layer 2d is formed on the first blocking layer 2c and the conductive structure pattern 2 is formed, for example, through photolithography process.

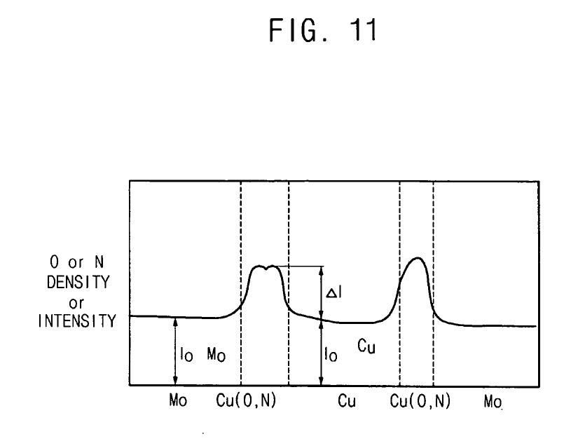

Existence of the first and second blocking layers 2c and 2e of the present conductive structure may be checked through a following method. Referring to FIG. 11, when barrier layer 2a and capping layer 2d includes molybdenum (Mo), and copper layer 2b includes copper (Cu), the existence of the first and second blocking layers 2c and 2e may be checked through detecting the density of oxygen or nitrogen by using a tool such as secondary ion mass spectroscopy (SIMS), x-ray photoelectron spectroscopy (XPS), etc.

When IOMo represents the density of oxygen, nitrogen or oxygen and nitrogen included in barrier layer or capping layer including molybdenum, and IOCu represents the density of oxygen, nitrogen or oxygen and nitrogen included in copper layer, ΔI represents [(density of oxygen, nitrogen or oxygen and nitrogen included in blocking layer)−(IOMo, IOCu, or average of IOMo and IOCu)], the blocking layer preferably satisfies the following equation.
5<[ΔI/IOMo×100, ΔI/IOCu×100, or 2×ΔI/(IOMo+IOCu)<10000.

The conductive structure and the method of manufacturing the conductive structure according to the present invention may be applied to a thin film transistor (TFT) substrate, a semiconductor device, an apparatus using a semiconductor, etc. employed by a liquid crystal display (LCD) apparatus, an organic light emitting device (OLED), etc. Additionally, the conductive structure and the method of manufacturing the conductive structure according to the present invention may be applied to other fields requiring minute patterns.

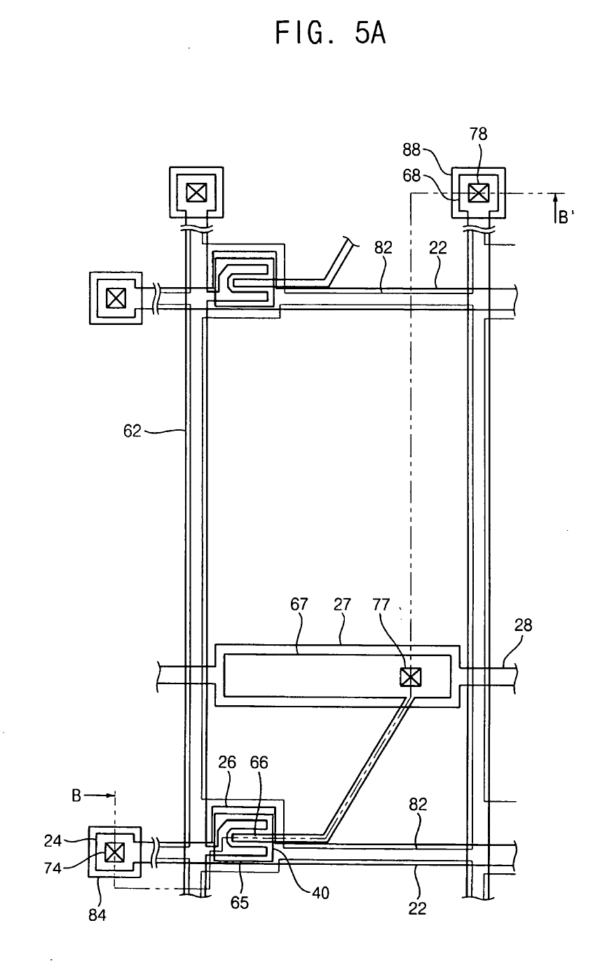

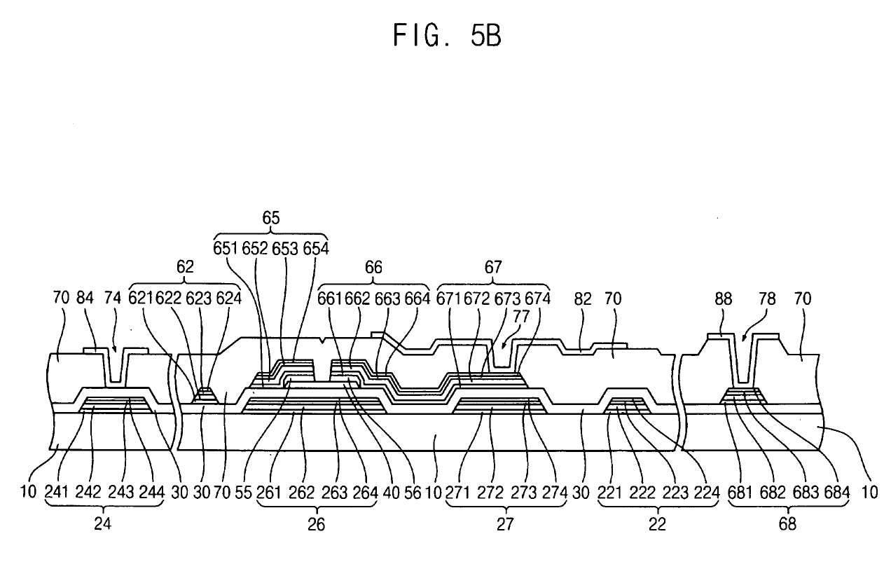

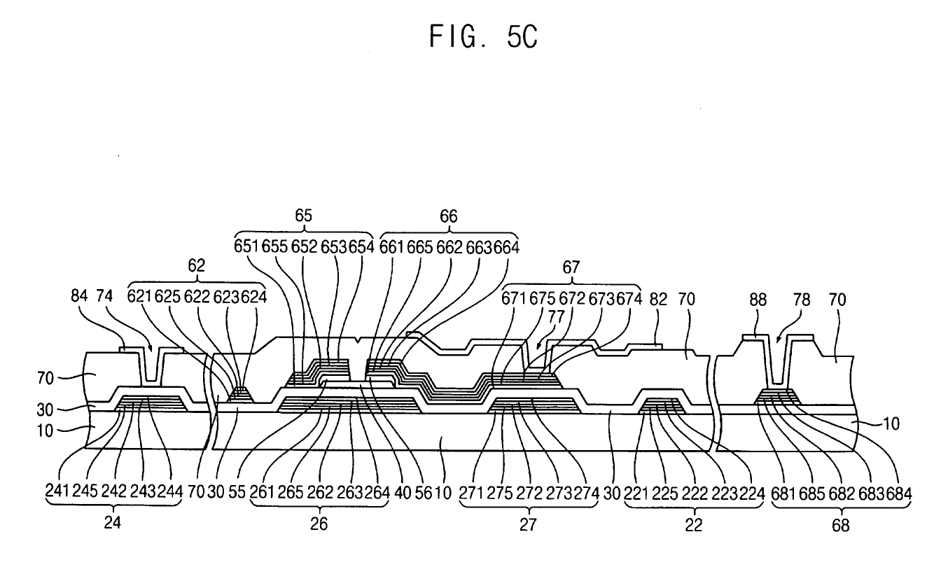

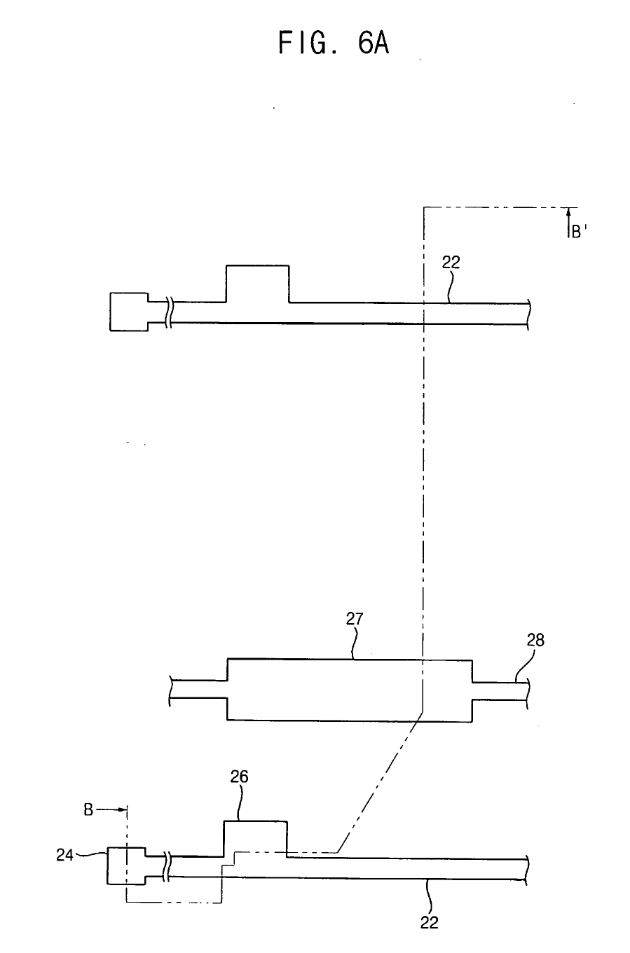

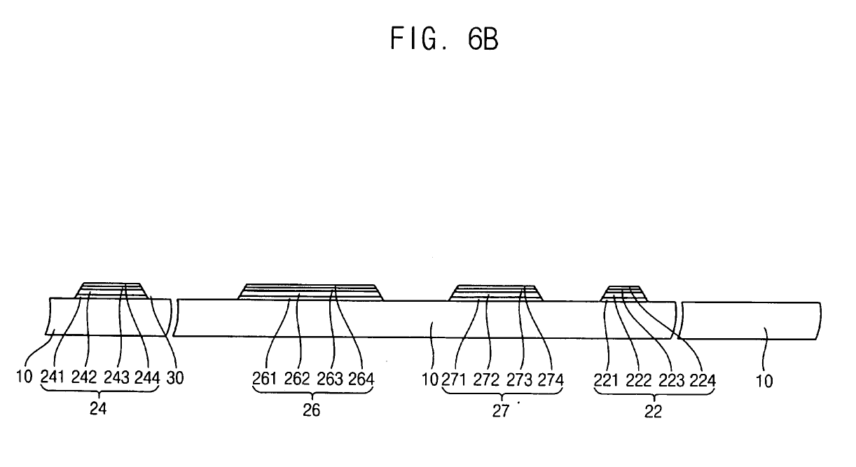

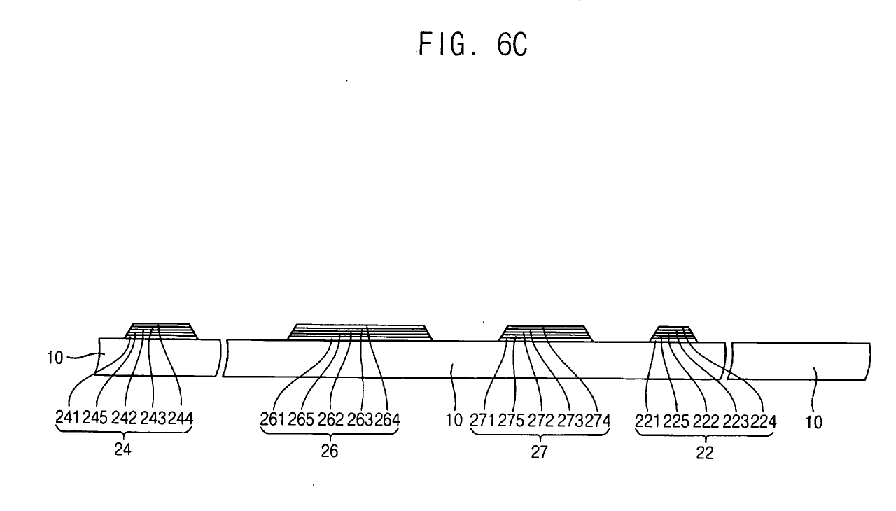

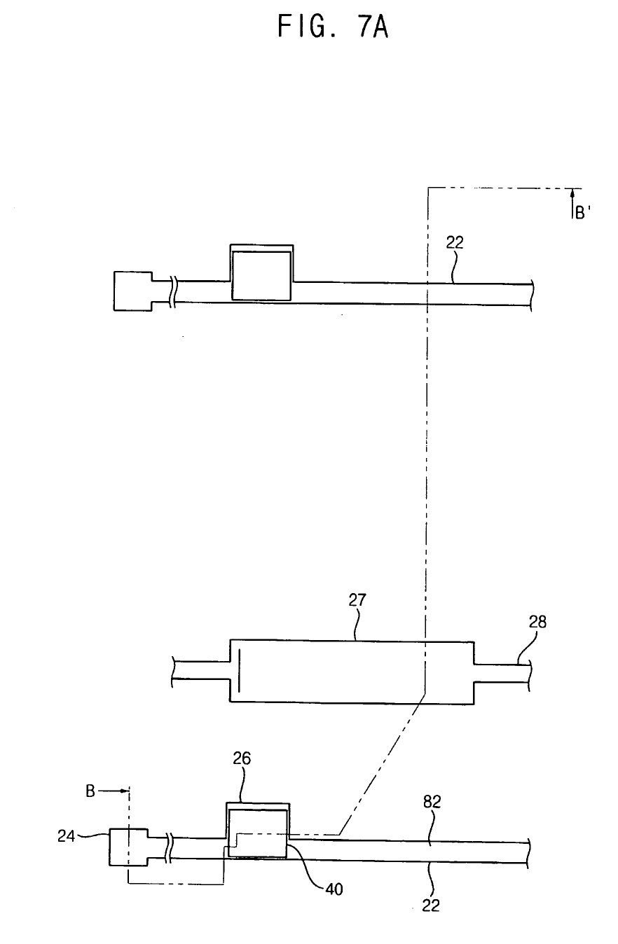

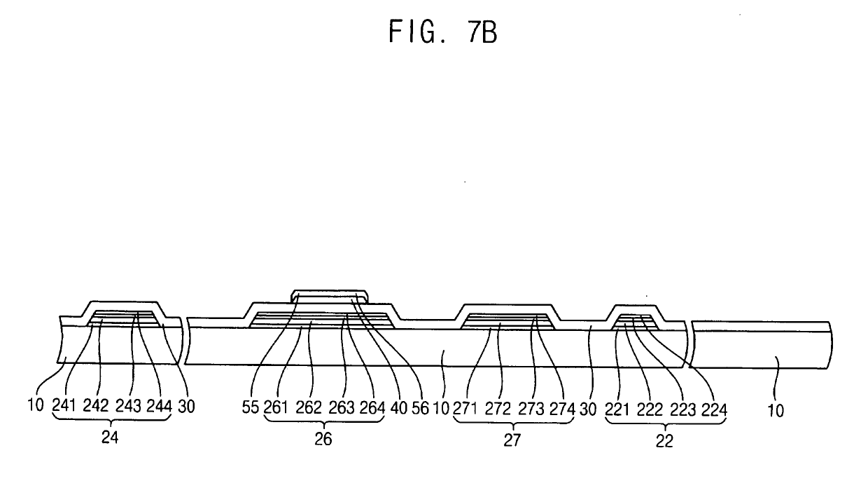

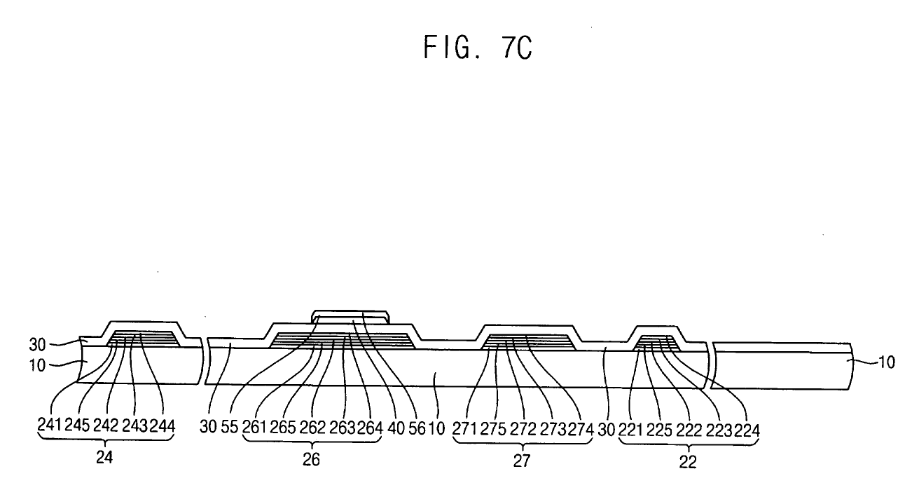

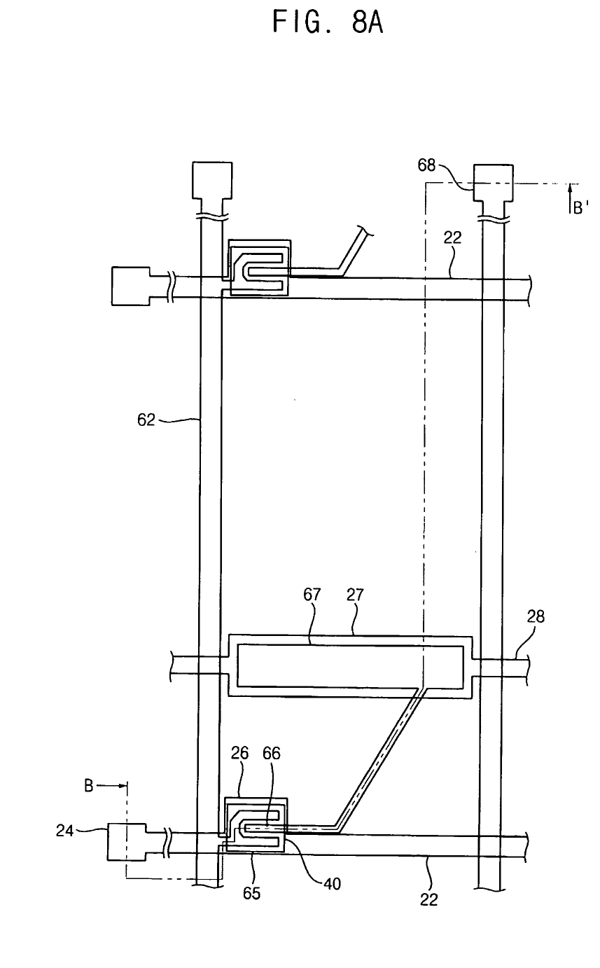

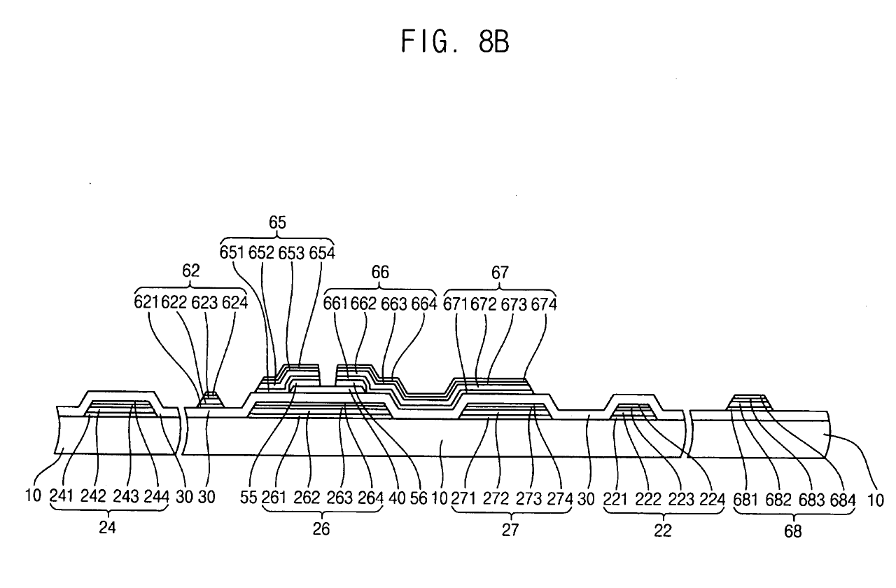

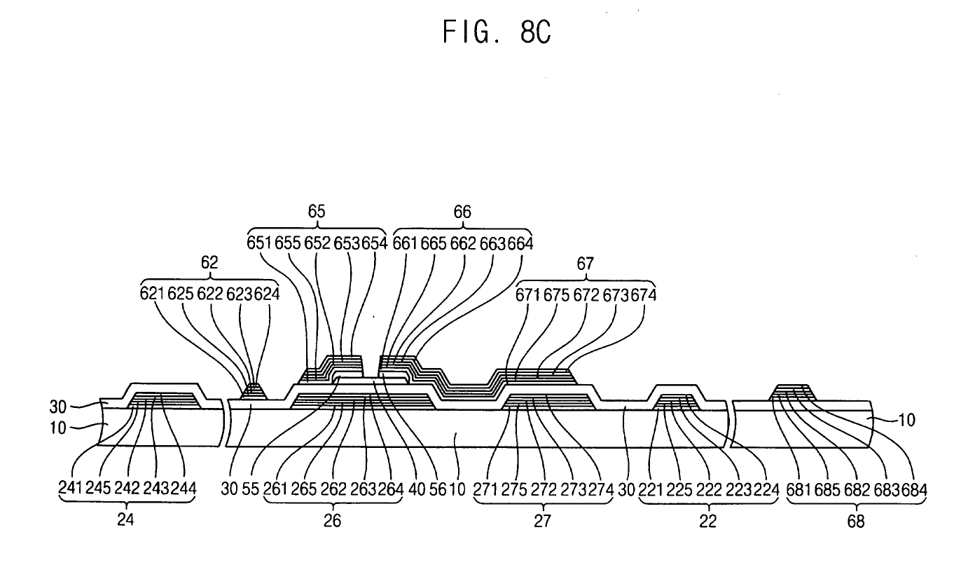

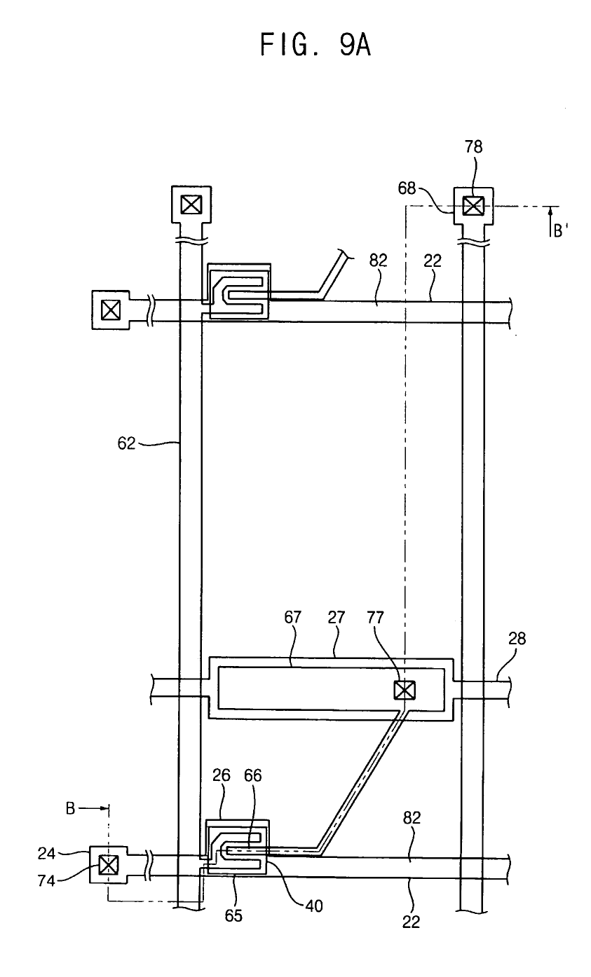

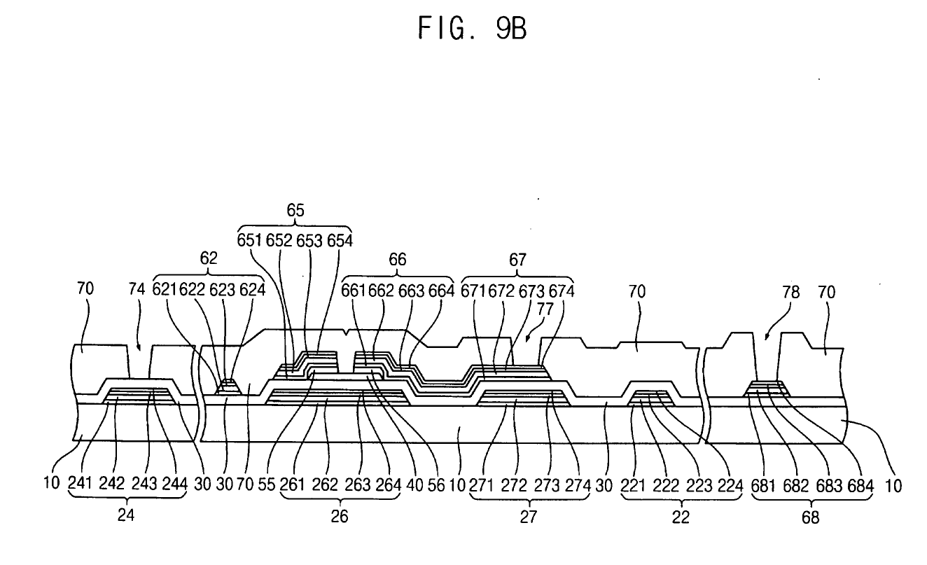

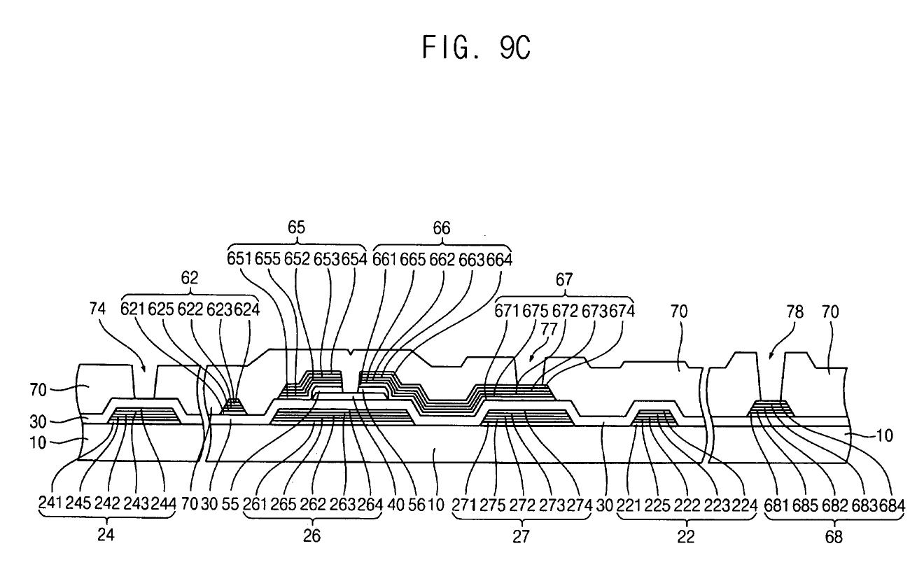

FIG. 5A is a layout illustrating a TFT substrate according to an example embodiment of the present invention, and FIGS. 5B and 5C are cross-sectional views taken along a line B-B′ in FIG. 5A. FIGS. 6A, 7A, 8A and 9A are plan views illustrating a method of manufacturing a TFT substrate according to an example embodiment of the present embodiment. FIGS. 6B and 6C are cross-sectional views taken along a line B-B′ in FIG. 6A. FIGS. 7B and 7C are cross-sectional views taken along a line B-B′ in FIG. 7A. FIGS. 8B and 8C are cross-sectional views taken along a line B-B′ in FIG. 8A. FIGS. 9B and 9C are cross-sectional views taken along a line B-B′ in FIG. 9A.

As shown in FIGS. 6A and 6B, a gate conductive structure transferring gate signal is formed on an insulation substrate 10. The gate conductive structure includes gate line 22, a gate line end portion 24, gate electrode 26, storage electrode 27 and storage electrode line 28. Gate line 22 is extended along a first direction. Gate line end portion 24 is electrically connected to an end of gate line 22 to transfer a gate signal of an external device to gate line 22. Gate electrode 26 is electrically connected to gate line 28.

Storage electrode 27 of each pixel is electrically connected to storage electrode line 28 extended through the pixel along the first direction. Storage electrode 27 overlaps drain electrode extended portion 67 that is electrically connected to pixel electrode 82 to for a storage capacitor that enhances capacitance for maintaining electric charges.

Storage electrode 27 and storage electrode line 28 may have various positions and shapes. For example, storage electrode 27 and storage electrode line 28 may be formed from a conductive structure that is different from the gate conductive structure. Furthermore, storage electrode 27 and storage electrode line 28 may not be formed when the storage capacitance is enough.

As shown in FIG. 5B, the gate conductive structure includes a barrier layer 221, 241, 261 and 271, a copper layer 222, 242, 262 and 272 including copper or copper alloy, a blocking layer 223, 243, 263 and 273 including copper nitride, copper oxide or copper oxinitride, a capping layer 224, 244, 264 and 274. As a result, the gate conductive structure has a four-layered structure. Now shown in FIG. 5B, storage electrode line 28 has the same structure as that of gate conductive structure 22, 24, 26 and 27. The characteristics of gate conductive structure 22, 24, 26 and 27, which will be explained, are applied also to storage electrode line 28.

Gate conductive structure 22, 24, 26 and 27 of the present embodiment has substantially the same structure as that of the above examples. That is, barrier layer 221, 241, 261 and 271 assists copper layer 222, 242, 262 and 272 so that copper layer 222, 242, 262 and 272 is fastened to the insulation substrate 10. Additionally, barrier layer 221, 241, 261 and 271 prevents diffusion of material between the insulation substrate 10 and copper layer 222, 242, 262 and 272.

Additionally, blocking layer 223, 243, 263 and 273 disposed between copper layer 222, 242, 262 and 272 and capping layer 224, 244, 264 and 274 prevents galvanic corrosion induced by electron exchange between copper layer 222, 242, 262 and 272 and capping layer 224, 244, 264 and 274. As a result, a profile defect such as the overhang of capping layer 224, 244, 264 and 274 is prevented.

No problem is induced even through copper ions diffuse into the insulation layer 10 disposed under gate conductive structure 22, 24, 26, 27 and 28 when gate conductive structure 22, 24, 26, 27 and 28 are simultaneously etched. Therefore, like capping layer 224, 244, 264 and 274, barrier layer 221,
241, 261 and 271 may include a material that may be simultaneously etched with copper layer 222, 242, 262 and 272.

Gate conductive structure 22, 24, 26, 27 and 28 has a four-layered structure having barrier layer 221, 241, 261 and 271, copper layer 222, 242, 262 and 272, blocking layer 223, 243, 263 and 273, and capping layer 224, 244, 264 and 274 as the conductive structure in FIG. 1.

Alternatively, gate conductive structure 22, 24, 26, 27 and 28 may have a five-layered structure having barrier layer 221, 241, 261 and 271, second blocking layer 225, 245, 265 and 275, copper layer 222, 242, 262 and 272, the first blocking layer 223, 243, 263 and 273, and capping layer 224, 244, 264 and 274 as the conductive structure in FIG. 5C. Gate conductive structure 22, 24, 26, 27 and 28 having a five-layered structure is substantially the same as the conductive structure in FIG. 4, and a method of manufacturing gate conductive structure 22, 24, 26, 27 and 28 is substantially the same as the method described above.

A gate insulation layer 30 is formed on substrate 10 having gate conductive structure 22, 24, 26, 27 and 28 formed thereon. Gate insulation layer 30 includes silicon nitride (SiNx), etc.

A semiconductor layer 40 is formed on gate insulation layer 30 disposed on gate substrate 10 having gate conductive structure 22, 24, 26, 27 and 28 formed thereon. Semiconductor layer 40 includes, for example, amorphous silicon. Ohmic contact layers 55 and 56, formed on semiconductor layer 40, include n+amorphous silicon having silicide or an n-type dopant.

A data conductive structure is formed on ohmic contact layer 55 and 56 and gate insulation layer 30. The data conductive structure includes a data line 62, a source electrode 65, a drain electrode 66, a drain electrode extended portion 67 and a data line end portion 68. Data line 62 is extended along a second direction that is different from the first direction, so that the data line and the gate line defines a pixel. Source electrode 65 is extended from data line 62 to be disposed over ohmic contact layer 55. Data line end portion 68 is electrically connected to an end portion of data line 62 to transfer an image signal provided from an external device to data line 62. Drain electrode 66 is spaced apart from the source electrode 65. Drain electrode 66 and the source electrode 65 are disposed at the opposite side with respect to a channel layer of the TFT. The drain electrode extended portion 67 is extended from drain electrode 66 to overlap with storage electrode 27.

Referring to FIG. 5B, like gate conductive structure 22, 24, 26 and 27, data conductive structure 62, 65, 66, 67 and 68 has a four-layered structure having barrier layer 621, 651, 661, 671 and 681, copper layer 622, 652, 662, 672 and 682, blocking layer 623, 653, 663, 673 and 683, and capping layer 624, 654, 664, 674 and 684. The conductive structure in FIG. 1 may be applied to data conductive structure 62, 65, 66, 67 and 68.

Barrier layer 621, 651, 661, 671 and 681 assists copper layer 622, 652, 662, 672 and 682 so that copper layer. 622, 652, 662, 672 and 682 is fastened to the substrate such as ohmic contact layer 55 and 56. Additionally, barrier layer 621, 651, 661, 671 and 681 prevents diffusion of the material between copper layer 622, 652, 662, 672 and 682, and ohmic contact layers 55 and 56 or between copper layer 622, 652, 662, 672 and 682, and gate insulation layer 30.

Additionally, barrier layer 621, 651, 661, 671 and 681 prevents copper ions in the etching solution from penetrating into ohmic contact layers 55 and 56 or into semiconductor layer 40 during the wet-etching process for forming data conductive structure 62, 65, 66, 67 and 68. As a result, deterioration of the TFT is prevented. Additionally, blocking layer 623, 653, 663, 673 and 683 is disposed between copper layer 622, 652, 662, 672 and 682 and capping layer 624, 654, 664, 674 and 684 to prevent galvanic corrosion induced by electron exchange.

Referring to FIG. 5C, data conductive structure 62, 65, 66, 67 and 68 may have five layers including barrier layer 621, 651, 661, 671 and 681, second blocking layer 625, 655, 665, 675 and 685, copper layer 622, 652, 662, 672 and 682, first blocking layer 623, 653, 663, 673 and 683, and capping layer 624, 654, 664, 674 and 684. The conductive structure in FIG. 4 may be applied to data conductive structure 62, 65, 66, 67 and 68.

At least a portion of the source electrode 65 overlaps semiconductor layer 40. Drain electrode 66 is disposed opposite to the source electrode 65 with respect to gate electrode 26. At least a portion of drain electrode 66 overlaps semiconductor layer 40. Ohmic contact layer 55 and 56 are disposed between semiconductor layer 40 and the source and drain electrodes 65 and 66 to lower contact resistance.

Drain electrode extended portion 67 overlaps storage electrode 27 with gate insulation layer 30 disposed therebetween to define a storage capacitor. When storage electrode 27 is not required, drain electrode extended portion 67 is not formed.

Gate electrode 26, semiconductor layer 40 formed on gate electrode 26, ohmic contact layer 55 and 56 disposed on semiconductor layer 40, the source electrode 65 and drain electrode 66 define a TFT. Semiconductor layer 40 corresponds to a channel of the TFT.

A protection layer 70 is formed on data conductive structure 62, 65, 66, 67 and 68, and semiconductor layer 40 not covered by data conductive structure 62, 65, 66, 67 and 68. For example, protection layer 70 may include a material that has a good planarizing property, and is photosensitive. Protection layer 70 may include a material such as a-Si:C:O, a-Si:O:F, etc, which may have a low permittivity and may be formed by plasma enhanced chemical vapor deposition (PECVD). Alternatively, protection layer 70 may include an inorganic material such as silicon nitride (SiNx), etc. When protection layer 70 includes an organic material, an insulation layer (not shown) including silicon nitride (SiNx), silicon oxide (SiO₂), etc. may be additionally formed under protection layer 70 having an organic material in order to prevent a contact between protection layer 70 and semiconductor layer 40 exposed between the source electrode 65 and drain electrode 66.

Protection layer 70 includes contact holes 77 and 78 exposing drain electrode extended portion 67 and data line end portion 68, respectively. Protection layer 70 and gate insulation layer 30 also include a contact hole 74 exposing gate line end portion 24. A pixel electrode 82 is formed on protection layer 70. Pixel electrode 82 is electrically connected to drain electrode 66 through the contact hole 77. Pixel electrode 82 is disposed in a pixel region. When an electric field is generated between pixel electrode 82 and a common electrode of an upper substrate, an arrangement of liquid crystal molecules is changed.

A sub gate line end portion 84 and a sub data line end portion 68 are formed on protection layer 70. Sub gate line end portion 84 and sub data line end portion 88 are electrically connected to gate line end portion 24 and data line end portion 68 through the contact holes 74 and 78, respectively. Pixel electrode 82 and sub gate line end portion 84 and sub data line end portion 88 include an electrically conductive and optically transparent material such as indium tin oxide (ITO), indium zinc oxide (IZO), etc. The TFT substrate according to the present example embodiment may be applied to a liquid crystal display (LCD) apparatus.

Hereinafter, a method of manufacturing the TFT substrate will be explained Referring to FIGS. 6A to 9C. As shown in FIGS. 6A and 6B, a gate multilayer is formed on insulation layer 10. Gate multilayer includes barrier layer 221, 241, 261 and 271, copper layer 222, 242, 262 and 272 including copper or copper alloy, blocking layer 223, 243, 263 and 273 including copper nitride, copper oxide or copper oxinitride, capping layer 224, 244, 264 and 274. The gate multilayer may be formed through a sputtering method. Then, a photo resist pattern defining gate conductive structure 22, 24, 26, 27 and 28 is formed on the gate multilayer. Capping layer 224, 244, 264 and 274, blocking layer 223, 243, 263 and 273, copper layer 222, 242, 262 and 272, and barrier layer 221, 241, 261 and 271 are wet-etched in sequence.

Alternatively, when capping layer 224, 244, 264 and 274, blocking layer 223, 243, 263 and 273, and copper layer 222, 242, 262 and 272 are wet-etched in sequence, barrier layer 221, 241, 261 and 271 may be dry-etched by using the photo resist pattern as a mask. Then, the photo resist pattern is removed. Alternatively, when capping layer 224, 244, 264 and 274, blocking layer 223, 243, 263 and 273, and copper layer 222, 242, 262 and 272 are wet-etched in sequence, the photo resist pattern is removed and barrier layer 221, 241, 261 and 271 may be dry-etched by using capping layer 224, 244, 264 and 274, blocking layer 223, 243, 263 and 273, and copper layer 222, 242, 262 and 272, which are wet-etched, as a mask. As a result, the gate conductive structure including gate line 22, gate electrode 26, gate line end portion 24, storage electrode 27 and storage electrode line 28 is completed.

The method of manufacturing conductive structure described referring to FIGS. 3A to 3D may be applied to the method of gate conductive structure 22, 24, 26, 27 and 28. That is, blocking layer 223, 243, 263 and 273 may be formed through a reactive sputtering method using copper as a target and performed in a chamber filled with nitrogen gas or oxygen gas. A portion of blocking layer 223, 243, 263 and 273 may be formed by forming a natural oxide layer through a vacuum break.

Referring to FIG. 6C, gate conductive structure 22, 24, 26, 27 and 28 has a five-layered structure having barrier layer 221, 241, 261 and 271, second blocking layer 225, 245, 265 and 275, copper layer 222, 242, 262 and 272, the first blocking layer 223, 243, 263 and 273, and capping layer 224, 244, 264 and 274. Gate conductive structure 22, 24, 26, 27 and 28 has a substantially same structure as that in FIG. 4, and a method of manufacturing gate conductive structure 22, 24, 26, 27 and 28 is also the same as described above.

When barrier layer 221, 241, 261 and 271 is formed, a reactive sputtering using copper as a target is performed in a chamber filled with argon gas together with oxygen gas or nitrogen gas to form second blocking layer 225, 245, 265 and 275. Then, providing nitrogen gas or oxygen gas is stopped, and sputtering is performed in the chamber filled with argon gas to form copper layer 222, 242, 262 and 272. Then, oxygen gas or nitrogen gas is provided to the chamber again in order to form the first blocking layer 223, 243, 263 and 273. A portion of the first blocking layer 223, 243, 263 and 273 may be formed by forming a natural oxide layer formed on copper layer 222, 242, 262 and 272 through a vacuum break, when second blocking layer 225, 245, 265 and 275 and copper layer 222, 242, 262 and 272 are formed.

Gate conductive structure 22, 24, 26, 27 and 28 includes first blocking layer 223, 243, 263 and 273 disposed between copper layer 222, 242, 262 and 272 and capping layer 224, 244, 264 and 274 to reduce a galvanic corrosion by preventing electron exchange between copper layer 222, 242, 262 and 272 and capping layer 224, 244, 264 and 274, and second blocking layer 225, 245, 265 and 275 disposed between barrier layer 221, 241, 261 and 271 and copper layer 222, 242, 262 and 272 to reduce a galvanic corrosion by preventing electron exchange between barrier layer 221, 241, 261 and 271 and copper layer 222, 242, 262 and 272. Therefore, the conductive structure may be formed to have a complete profile having no overhang, and a satisfactory tapered angle.

Then, as described in FIGS. 7A to 7C, gate insulation layer 30 including, for example, silicon nitride is formed such that gate insulation layer 30 has a thickness of about 1,500 angstroms to about 5000 angstroms. An intrinsic amorphous silicon layer is formed on gate insulation layer 30 such that the amorphous silicon layer has a thickness of about 500 angstroms to about 2000 angstroms in order to form semiconductor layer 40, and a dopped amorphous silicon layer is formed on the intrinsic amorphous silicon layer such that the dopped amorphous silicon layer has a thickness of about 300 angstroms to about 600 angstroms in order to form ohmic contact layer 55. The intrinsic amorphous silicon layer and the dopped amorphous silicon layer are patterned through a photolithography method to form semiconductor layer 40 and ohmic contact layer 55, respectively.

Then, Referring to FIGS. 8A and 8B, the data conductive structure multilayer including barrier layer 621, 651, 661, 671 and 681, copper layer 622, 652, 662, 672 and 682, blocking layer 623, 653, 663, 673 and 683, and capping layer 624, 654, 664, 674 and 684 is formed. Each of barrier layer 621, 651, 661, 671 and 681, copper layer 622, 652, 662, 672 and 682, blocking layer 623, 653, 663, 673 and 683, and capping layer 624, 654, 664, 674 and 684 may be formed in sequence through a sputtering method. Barrier layer 621, 651, 661, 671 and 681 is formed on gate insulation layer 30 and ohmic contact layer 50. Copper layer 622, 652, 662, 672 and 682 includes copper or copper alloy. Blocking layer 623, 653, 663, 673 and 683 includes copper nitride, copper oxide or copper oxinitride.

Then, a photo resist pattern defining data conductive structure 62, 65, 66, 67 and 68 is formed on the data conductive structure multilayer, and capping layer 624, 654, 664, 674 and 684, blocking layer 623, 653, 663, 673 and 683, copper layer 622, 652, 662, 672 and 682, and barrier layer 621, 651, 661, 671 and 681 are simultaneously etched by using the photo resist pattern as an etching mask. Alternatively, capping layer 624, 654, 664, 674 and 684, blocking layer 623, 653, 663, 673 and 683, and copper layer 622, 652, 662, 672 and 682 may be simultaneously wet-etched to expose barrier layer 621, 651, 661, 671 and 681, and then barrier layer 621, 651, 661, 671 and 681 may be dry-etched by using the photo resist pattern as an etching mask. Alternatively, when capping layer 624, 654, 664, 674 and 684, blocking layer 623, 653, 663, 673 and 683, and copper layer 622, 652, 662, 672 and 682 may be simultaneously wet-etched to expose barrier layer 621, 651, 661, 671 and 681, the photo resist pattern may be removed, and then barrier layer 621, 651, 661, 671 and 681 may be dry-etched by using capping layer 624, 654, 664, 674 and 684, blocking layer 623, 653, 663, 673 and 683, and copper layer 622, 652, 662, 672 and 682, which are patterned, as an etching mask. Furthermore, barrier layer 621, 651, 661, 671 and 681, ohmic contact layer 55 and 56, and semiconductor layer 40 may be simultaneously etched.

As a result, the data conductive structure having data line 62 extended along a direction that is substantially perpendicular to that of gate line 22, the source electrode 65 that is electrically connected to data line 62 and extended to be disposed over gate electrode 26, data line end portion 68 that is electrically connected to data line 62, drain electrode 66 disposed opposite to the source electrode 65 with respect to gate electrode 26, and drain electrode extended portion 67 that is extended from drain electrode 66 to overlap with storage electrode 27 is completed.

Data conductive structure 62, 65, 66, 67 and 68 may be formed through a method of manufacturing a conductive structure described above. In other words, blocking layer 623, 653, 663, 673 and 683 disposed between copper layer 622, 652, 662, 672 and 682, and capping layer 624, 654, 664, 674 and 684 prevents electron exchange between copper layer 622, 652, 662, 672 and 682, and capping layer 624, 654, 664, 674 and 684 to prevent galvanic corrosion. Therefore, data conductive structure 62, 65, 66, 67 and 68 has a satisfactory side profile and the overhang is prevented.

Referring to FIG. 8C, like gate conductive structure 22, 24, 26 and 27, data conductive structure 62, 65, 66, 67 and 68 may have five-layered structures. That is, second blocking layer 625, 655, 665, 675 and 685 may be additionally formed between copper layer 622, 652, 662, 672 and 682 and barrier layer 621, 651, 661, 671 and 681. When second blocking layer 625, 655, 665, 675 and 685 is formed between copper layer 622, 652, 662, 672 and 682 and barrier layer 621, 651, 661, 671 and 681, data conductive structure 62, 65, 66, 67 and 68 has more enhanced profile. The method of manufacturing data conductive structure 62, 65, 66, 67 and 68 is substantially the same as that in FIG. 4.

Then, barrier layer 621, 651, 661, 671 and 681 is dry-etched, and a portion of ohmic contact layer 50, which is not covered by data conductive structure 65, 66, 67 and 68 is dry-etched to expose semiconductor layer 40. The etched portion of ohmic contact layer 50 is disposed over gate electrode 26. Gas used for etching barrier layer 621, 651, 661, 671 and 681 may also be used to etch ohmic contact layer 50. Alternatively, gas for etching ohmic contact layer 70 may be changed and the changed gas may be used to etch ohmic contact layer 50. As a result, gate electrode 26, semiconductor layer 40 formed on gate electrode 26, ohmic contact layer 55 and 56, the source electrode 65 and drain electrode 66 are completed to define a bottom gate type thin film transistor having a gate electrode disposed under a channel layer.

Referring to FIGS. 9A to 9C, protection layer 70 is formed on data conductive structure 62, 65, 66, 67 and 68, and semiconductor layer 40 not covered by data conductive structure 62, 65, 66, 67 and 68. For example, protection layer 70 may include a material that has a good planarizing property, and is photosensitive. Protection layer 70 may include a material such as a-Si:C:O, a-Si:O:F, etc, which may have a low permittivity and may be formed by plasma enhanced chemical vapor deposition (PECVD). Alternatively, protection layer 70 may include an inorganic material such as silicon nitride (SiNx), etc. Protection layer 70 may have a single layered structure or a multilayered structure having various kinds of material.

Then, protection layer 70 and gate insulation layer 30 are patterned to form the contact hole 74, 77 and 78 exposing gate line end portion 24, drain electrode extended portion 67 and data line end portion 68 through a photolithography process. When protection layer 70 and gate insulation layer 30 include a photosensitive organic material, the contact hole 74, 77 and 78 may be formed only through a photolithography process. Preferably, protection layer 70 and gate insulation layer 30 may have a same etching selectivity.

Then, as shown in FIGS. 5A to 5C, an ITO layer is formed on protection layer 70, and the ITO layer is patterned to form pixel electrode 82 that is electrically connected to drain electrode 66 through the contact hole 77, sub gate line end portion 84 that is electrically connected to gate line end portion 24 through the contact hole 74, and sub data line end portion 88 that is electrically connected to data line end portion 68 through the contact hole 78.

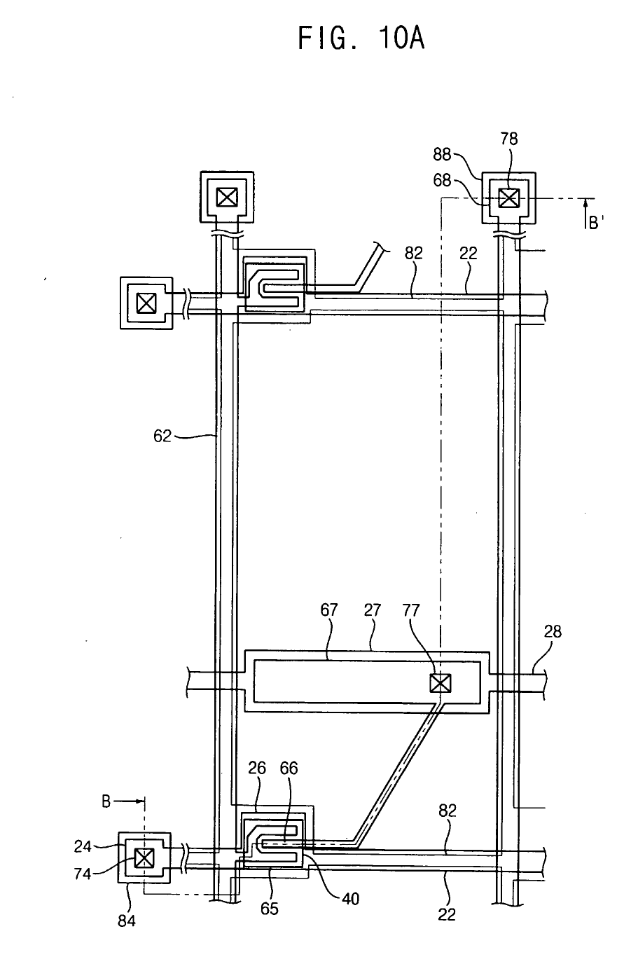

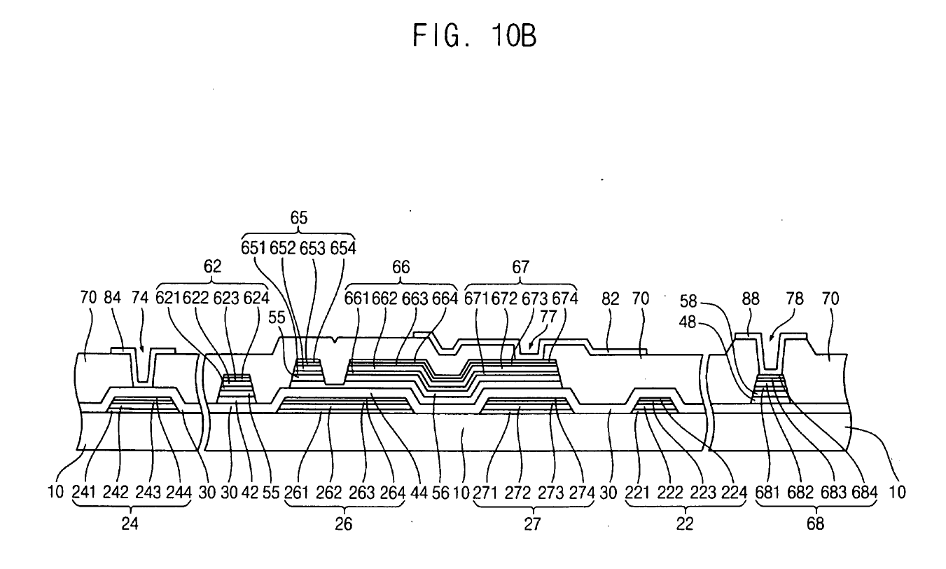

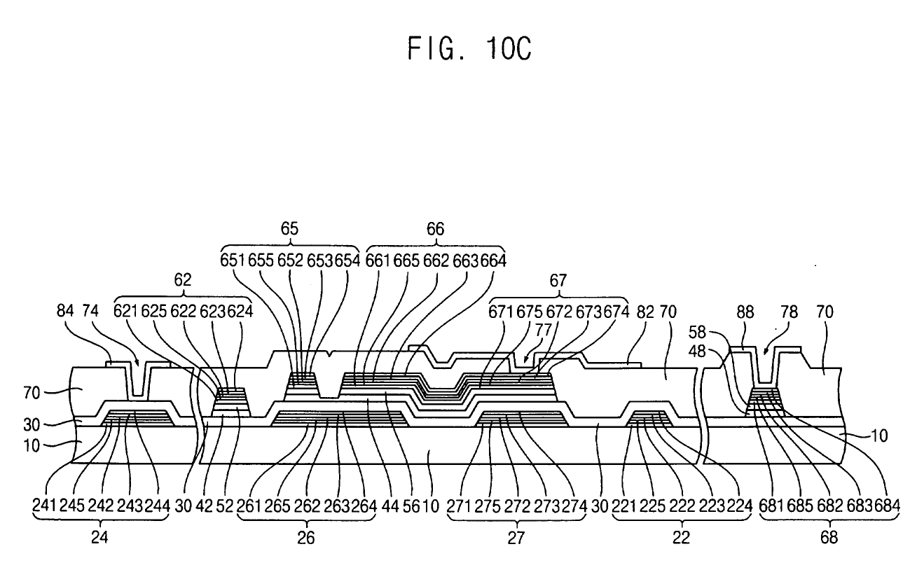

Hereinbefore, the TFT substrate including the semiconductor layer having an island shape and a different pattern from that of the data conductive structure, and the method of manufacturing the TFT substrate was explained. However, the present invention may be applied to a TFT substrate including a semiconductor layer having a substantially same pattern as that of the data conductive structure, and the method of manufacturing the TFT substrate. Hereinafter, the TFT substrate including a semiconductor layer having a substantially same pattern as that of the data conductive structure, and the method of manufacturing the TFT substrate will be explained referring to FIGS. 10A to 10C.

FIG. 10A is a layout illustrating a TFT substrate according to another example embodiment of the present invention, and FIGS. 10B and 10C are cross-sectional views taken along a line B-B′ in FIG. 10A. As shown in FIGS. 10A to 10C, an example embodiment of the present invention is substantially the same as that in FIGS. 6A to 6C except the fact that semiconductor layer 42, 44 and 48 and ohmic contact layer 52, 55, 56 and 58 have substantially the same structure as that of data conductive structure 62, 65, 66, 67 and 68. Ohmic contact layer 52, 55, 56 and 58 has substantially the same structure as that of data conductive structure 62, 65, 66, 67 and 68, and ohmic contact layer 52, 55, 56 and 58 is not divided at a channel region. Unlike a previous example in which the semiconductor layer and the data conductive structure are formed through different masks, according to a method of manufacturing a TFT substrate according to the present embodiment, the data conductive structure and the ohmic contact layer are patterned through one mask having slit or half-tone mask.

Other processes are substantially the same as that in the previous example, and a person skilled in the art may perform the processes. Therefore, any other explanation will be omitted. According to the conductive structure and a method of manufacturing the conductive structure of the present invention, copper layer may be tightly attached to the substrate and oxidation or corrosion of copper layer may be prevented. Additionally, overhang induced by the corrosion may be prevented, so that the conductive structure has a satisfactory profile. Therefore, a reliability of copper layer having a relatively low resistivity is enhanced.

According to the TFT substrate and the method of manufacturing the TFT substrate, the reliability of the gate conductive structure and the data conductive structure is enhanced, so that signal characteristics and display quality are enhanced.

Having described the example embodiments of the present invention and its advantages, various changes, substitutions and alterations will be apparent to those skilled in the art and may be made without, however, departing from the spirit and scope of the invention.

What is claimed is:

1. A conductive structure comprising:
a barrier layer formed on a substrate;
a copper layer formed on the barrier layer, the copper layer including copper or copper alloy;
a blocking layer formed on the copper layer; and
a capping layer formed on the blocking layer.

2. The conductive structure of claim 1, wherein the barrier layer comprises molybdenum (Mo), molybdenum nitride (MoN) or molybdenum alloy.

3. The conductive structure of claim 2, wherein the molybdenum alloy comprises any one selected from the group consisting of MoW, MoTi, MoNb, MoZr and a mixture thereof.

4. The conductive structure of claim 1, wherein the blocking layer comprises copper nitride.

5. The conductive structure of claim 1, wherein the blocking layer comprises copper oxide.

6. The conductive structure of claim 1, wherein the blocking layer comprises copper oxinitride.

7. The conductive structure of claim 1, wherein the capping layer comprises molybdenum, molybdenum nitride (MoN) or molybdenum alloy.

8. The conductive structure of claim 7, wherein the molybdenum alloy comprises any one selected from the group consisting of MoW, MoTi, MoNb, MoZr and a mixture thereof.

9. The conductive structure of claim 1, wherein the substrate corresponds to an insulation substrate, a semiconductor layer or an insulation layer.

10. A conductive structure comprising:
a barrier layer formed on a substrate;
a first blocking layer formed on the barrier layer;
a copper layer formed on the first blocking layer, the copper layer including copper or copper alloy;
a second blocking layer formed on the copper layer; and
a capping layer formed on the second blocking layer.

11. The conductive structure of claim 10, wherein the barrier layer comprises molybdenum (Mo), molybdenum nitride (MoN) or molybdenum alloy.

12. The conductive structure of claim 11, wherein the molybdenum alloy comprises any one selected from the group consisting of MoW, MoTi, MoNb, MoZr and a mixture thereof.

13. The conductive structure of claim 10, wherein at least one of the first and second blocking layers comprises copper nitride.

14. The conductive structure of claim 10, wherein at least one of the first and second blocking layers comprises copper oxide.

15. The conductive structure of claim 10, wherein at least one of the first and second blocking layers comprises copper oxinitride.

16. The conductive structure of claim 10, wherein the capping layer comprises molybdenum, molybdenum nitride (MoN) or molybdenum alloy.

17. The conductive structure of claim 16, wherein the molybdenum alloy comprises any one selected from the group consisting MoW, MoTi, MoNb, MoZr and a mixture thereof.

18. The conductive structure of claim 10, wherein the substrate corresponds to an insulation substrate, a semiconductor layer or an insulation layer.

19. A method of manufacturing a conductive structure, comprising:
forming a barrier layer on a substrate;
forming a copper layer including copper or copper alloy on the substrate having barrier layer formed thereon;
forming a blocking layer on the copper layer; and
forming a capping layer on the blocking layer.

20. The method of claim 19, wherein the blocking layer is formed by a sputtering method using copper as a target in a chamber filled with nitrogen gas.

21. The method of claim 19, wherein the blocking layer is formed by a sputtering method using copper as a target in a chamber filled with oxygen gas.

22. The method of claim 19, wherein the blocking layer is formed by a sputtering method using copper as a target in a chamber filled with oxygen gas and nitrogen gas.

23. The method of claim 19, wherein the blocking layer is formed by a vacuum break.

24. A method of manufacturing a conductive structure, comprising:
forming a barrier layer on a substrate;
forming a first blocking layer on the barrier layer;
forming a copper layer including copper or copper alloy on the first blocking layer;
forming a second blocking layer on the copper layer; and
forming a capping layer on the second blocking layer.

25. The method of claim 24, wherein at least one of the first blocking layer and the second blocking layer is formed by a sputtering method using copper as a target in a chamber filled with nitrogen gas.

26. The method of claim 24, wherein at least one of the first blocking layer and the second blocking layer is formed by a sputtering method using copper as a target in a chamber filled with oxygen gas.

27. The method of claim 24, wherein at least one of the first blocking layer and the second blocking layer is formed by a sputtering method using copper as a target in a chamber filled with oxygen gas and nitrogen gas.

28. The method of claim 24, wherein the second blocking layer is formed by a vacuum break.

29. A thin film transistor (TFT) substrate comprising:
a gate conductive structure including a gate line that is formed on an insulation substrate and extends along a first direction, and a gate electrode that is electrically connected to the gate line;
a data conductive structure including a data line that is formed on the insulation substrate such that the data line is electrically insulated from the gate line, a source electrode that is electrically connected to the data line, and a drain electrode that is spaced apart from the source electrode, the data line extending along a second direction that is different from the first direction; and
a pixel electrode that is electrically connected to the drain electrode, the pixel electrode being formed in a pixel defined by the gate line and the data line,
wherein at least one of the gate conductive structure and the data conductive structure comprises:
a barrier layer formed on a substrate;
a copper layer formed on barrier layer, the copper layer including copper or copper alloy;
a blocking layer formed on the copper layer; and
a capping layer formed on the blocking layer.

30. The TFT substrate of claim 29, wherein the barrier layer comprises molybdenum (Mo), molybdenum nitride (MoN) or molybdenum alloy.

31. The TFT substrate of claim 30, wherein the molybdenum alloy comprises any one selected from the group consisting of MoW, MoTi, MoNb, MoZr and a mixture thereof.

32. The TFT substrate of claim 29, wherein the blocking layer comprises copper nitride.

33. The TFT substrate of claim 29, wherein the blocking layer comprises copper oxide.

34. The TFT substrate of claim 29, wherein the blocking layer comprises copper oxinitride.

35. The TFT substrate of claim 29, wherein the capping layer comprises molybdenum, molybdenum nitride (MoN) or molybdenum alloy.

36. The TFT substrate of claim 35, wherein the molybdenum alloy comprises any one selected from the group consisting of MoW, MoTi, MoNb, MoZr and a mixture thereof.

37. A thin film transistor (TFT) substrate comprising:
a gate conductive structure including a gate line that is formed on an insulation substrate and extends along a first direction, and a gate electrode that is electrically connected to the gate line;
a data conductive structure including a data line that is formed on the insulation substrate such that the data line is electrically insulated from the gate line, a source electrode that is electrically connected to the data line, and a drain electrode that is spaced apart from the source electrode, the data line extending along a second direction that is different from the first direction; and
a pixel electrode that is electrically connected to the drain electrode; the pixel electrode being formed in a pixel defined by the gate line and the data line,
wherein at least one of the gate conductive structure and the data conductive structure comprises:
a barrier layer formed on a substrate;
a first blocking layer formed on the barrier layer;
a copper layer formed on the first blocking layer, the copper layer including copper or copper alloy;
a second blocking layer formed on the copper layer; and
a capping layer formed on the second blocking layer.

38. The TFT substrate of claim 37, wherein barrier layer comprises molybdenum (Mo), molybdenum nitride (MoN) or molybdenum alloy.

39. The TFT substrate of claim 38, wherein the molybdenum alloy comprises any one selected from the group consisting of MoW, MoTi, MoNb, MoZr and a mixture thereof.

40. The TFT substrate of claim 37, wherein at least one of the first and second blocking layers comprises copper nitride.

41. The TFT substrate of claim 37, wherein at least one of the first and second blocking layers comprises copper oxide.

42. The TFT substrate of claim 37, wherein at least one of the first and second blocking layers comprises copper oxinitride.

43. The TFT substrate of claim 37, wherein the capping layer comprises molybdenum, molybdenum nitride (MoN) or molybdenum alloy.

44. The TFT substrate of claim 43, wherein the molybdenum alloy comprises any one selected from the group consisting of MoW, MoTi, MoNb, MoZr and a mixture thereof.
